(19) United States
(12) Patent Application Publication
(10) Pub. No.: US 2026/0071095 A1
(43) Pub. Date: Mar. 12, 2026

(54) POLISHING COMPOSITION, POLISHING METHOD, AND METHOD FOR PRODUCING SEMICONDUCTOR SUBSTRATE

(71) Applicant: Fujimi Incorporated, Kiyosu-shi (JP)

(72) Inventors: Masaki TADA, Kiyosu-shi (JP); Noriyuki TANAKA, Kiyosu-shi (JP); Akane KUMAYAMA, Kiyosu-shi (JP); Daichi JIMBO, Kiyosu-shi (JP)

(73) Assignee: Fujimi Incorporated, Kiyosu-shi (JP)

(21) Appl. No.: 19/319,501

(22) Filed: Sep. 4, 2025

(30) Foreign Application Priority Data
Sep. 9, 2024 (JP) 2024-154741

(51) Int. Cl. C09G 1/02; H01L 21/306

(52) U.S. Cl. CPC C09G 1/02; H10P 52/402

(57) ABSTRACT

The present disclosure provides a means by which a good polishing removal rate for an object to be polished including a silicon-containing material can be realized while at the same time reducing scratches on the surface of the object to be polished that has been polished. The present disclosure is a polishing composition containing: abrasive grains having a zeta potential of −5 mV or less; a first polyoxyalkylene compound having a weight average molecular weight of 100 or more and 900 or less; and a second polyoxyalkylene compound having an oxyalkylene unit different from that of the first polyoxyalkylene compound and having a weight average molecular weight of 100 or more and 900 or less, wherein the polishing composition has a pH of less than 7.

### TECHNICAL FIELD

The present disclosure relates to a polishing composition, a polishing method, and a method for producing a semiconductor substrate.

### BACKGROUND ART

In recent years, as the multi level interconnection of semiconductor substrate surfaces has progressed, a so-called chemical mechanical polishing (CMP) technology has been utilized, which physically polishes and flattens semiconductor substrates when producing devices. The CMP is a method for flattening the surface of an object to be polished (polishing object) such as a semiconductor substrate using a polishing composition (slurry) that contains abrasive grains such as silica, alumina or ceria, an anti-corrosion agent, a surfactant, or the like. The object to be polished (polishing object) is silicon, polysilicon, silicon oxide (SiO₂), carbon-containing silicon oxide (SiOC), silicon nitride (SiN), a wiring or plug composed of metal, or the like.

For example, JP 2022-56348 A (corresponding to US 2022/098441 A1) discloses a polishing composition containing silica having an organic acid fixed to the surface thereof and polyalkylene glycol, wherein the molecular weight distribution in terms of polyethylene glycol by gel permeation chromatography (GPC) for the polyalkylene glycol has two or more peaks, at least one peak of the molecular weight distribution is a peak with a peak top molecular weight of 1,000 or more and 6,000 or less, at least one peak of the molecular weight distribution is a peak with a peak top molecular weight of 100 or more and 800 or less, the polyalkylene glycol contains polyethylene glycol, at least one of the peaks with a peak top molecular weight of 1,000 or more and 6,000 or less is a peak derived from polyethylene glycol, and the polishing composition has a pH of 3 or more and 6 or less.

### SUMMARY

However, the technology described in JP 2022-56348 A (corresponding to US 2022/098441 A1) demonstrates a good polishing removal rate for an object to be polished, but there is still room for improvement in terms of reducing defects on the surface of the object to be polished that has been polished.

Therefore, an object of the present disclosure is to provide a means by which a good polishing removal rate for an object to be polished including a silicon-containing material can be realized while at the same time further reducing defects on the surface of the object to be polished that has been polished.

The inventors of the present disclosure have carried out diligent investigations in order to solve the problem described above. As a result, the inventors of the present disclosure have found that the above problem is solved by a polishing composition containing: abrasive grains having a zeta potential of −5 mV or less; a first polyoxyalkylene compound having a weight average molecular weight of 100 or more and 900 or less; and a second polyoxyalkylene compound having an oxyalkylene unit different from that of the first polyoxyalkylene compound and having a weight average molecular weight of 100 or more and 900 or less, wherein the polishing composition has a pH of less than 7, thereby leading to the completion of the disclosure of the present disclosure.

### DESCRIPTION OF EMBODIMENTS

According to one embodiment of the present disclosure, there is provided a polishing composition containing: abrasive grains having a zeta potential of −5 mV or less; a first polyoxyalkylene compound having a weight average molecular weight of 100 or more and 900 or less; and a second polyoxyalkylene compound having an oxyalkylene unit different from that of the first polyoxyalkylene compound and having a weight average molecular weight of 100 or more and 900 or less, wherein the polishing composition has a pH of less than 7.

According to such a polishing composition of the present disclosure, a good polishing removal rate for an object to be polished including a silicon-containing material can be realized while at the same time reducing defects on the surface of the object to be polished that has been polished.

Although the details of the reason why the above effect can be obtained by the polishing composition of the present disclosure are not clear, the reason is thought to be the mechanism as follows. Note that the mechanism is based on speculation, and the technical scope of the present disclosure is not restricted in any way by the mechanism.

The polishing composition of the present disclosure contains a first polyoxyalkylene compound and a second polyoxyalkylene compound having an oxyalkylene unit different from that of the first polyoxyalkylene compound. These two polyoxyalkylene compounds have hydrophilicity that differs from each other. If the hydrophilicity of the first polyoxyalkylene compound is higher than the hydrophilicity of the second polyoxyalkylene compound, then the second polyoxyalkylene compound, which has lower hydrophilicity (higher hydrophobicity), is adsorbed by the residue (in particular, organic residue) on the surface of the object to be polished. However, the residue that adsorbs the second polyoxyalkylene compound has high hydrophobicity, which makes it difficult to be dispersed in a dispersing medium (in particular, water) of the polishing composition. The first polyoxyalkylene compound, which has high hydrophilicity (low hydrophobicity), is further adsorbed by the residue by which the second polyoxyalkylene compound has been adsorbed, thereby increasing the hydrophilicity of the residue. This is thought to make it easier for the residue on the surface of the object to be polished to be dispersed in the dispersing medium, thereby reducing the residue and defects such as scratches on the object to be polished.

Embodiments of the present disclosure will be described in detail below, but the present disclosure is not limited to only the following embodiments and various modifications can be made within the scope of the claims. The embodiments described in the present specification can be optionally combined to make other embodiments. In the present specification, unless otherwise specified, operations and measurements of physical properties or other factors are carried out under conditions of room temperature (20° C. or higher and 25° C. or lower)/relative humidity of 40% RH or more and 50% RH or less.

In the present specification, the expression “X or more and Y or less” is used in the sense that it includes the numerical values listed before and after it (X and Y) as the lower limit value and the upper limit value. In the case where “X or more and Y or less” is listed more than once, for example, if “X1 or more and Y1 or less, or X2 or more and Y2 or less” is described, the disclosure of each numerical value as the upper limit, the disclosure of each numerical value as the lower limit, and the combination of those upper and lower limits are all disclosed (that is, they serve as the lawful basis for amendment). Specifically, amendment with X1 or more, amendment with Y2 or less, amendment with X1 or less, amendment with Y2 or more, amendment with X1 or more and X2 or less, amendment with X1 or more and Y2 or less, and others must all be considered lawful.

The content (concentration) described in the present specification may be the content (concentration) at the point of use (POU) or may be the concentration prior to dilution to the content (concentration) at the POU.

The terms “first” and “second” used in the present specification are used only for convenience in distinguishing the two types of polyoxyalkylene compounds from each other, and the ordering of “first” and “second” itself has no special meaning.

In the present specification, defects are a general term for foreign matter (in particular, organic residue) attached to the surface of the object to be polished that has been polished, as well as flaws (such as scratches) on the surface of the object to be polished that has been polished.

### [Abrasive Grains]

The polishing composition according to the present disclosure contains abrasive grains. The abrasive grains have the action of mechanically polishing an object to be polished, and improve the polishing removal rate for the object to be polished by the polishing composition.

In the polishing composition of the present disclosure, the abrasive grains have a zeta potential of −5 mV or less. Here, “zeta (Q potential” is the potential difference that occurs at the interface between a solid and a liquid in contact with each other when they are in relative motion. In the case where the zeta potential of the abrasive grains is more than −5 mV, defects on the surface of the object to be polished (in particular, silicon oxide) that has been polished are increased.

In the present disclosure, the zeta potential of the abrasive grains is preferably −60 mV or more and −10 mV or less, more preferably −50 mV or more and −10 mV or less, still more preferably −40 mV or more and −15 mV or less, and particularly preferably more than −35 mV and −15 mV or less. When the abrasive grains have a zeta potential in such a range, the polishing removal rate for the object to be polished can be further improved. Here, the zeta potential of the abrasive grains in the polishing composition is the value measured by the method described in Examples. Also, the zeta potential of the abrasive grains can be adjusted by the amount of anionic groups (in particular, organic acid groups) possessed by the abrasive grains, the pH of the polishing composition, and other factors, as described below.

There is no particular restriction on the type of the abrasive grains, and examples thereof include metal oxides such as silica, alumina, zirconia, and titania. As the abrasive grains, one type alone or a combination of two or more types can be used. Commercial products of the abrasive grains may be used and synthetic products thereof may also be used.

The type of the abrasive grains is preferably silica, and more preferably colloidal silica. Examples of the method for producing colloidal silica include the sodium silicate method and the sol-gel method, and colloidal silica produced by any production method can be suitably used as the abrasive grains of the present disclosure. However, from the viewpoint of reducing metallic impurities, colloidal silica produced by the sol-gel method, which can be produced with high purity, is preferable.

Production of colloidal silica by the sol-gel method can be carried out using a conventionally known method. Specifically, colloidal silica can be obtained by using a hydrolyzable silicon compound (for example, alkoxysilane or derivative thereof) as a raw material, and subjecting it to a hydrolysis and condensation reaction.

In some embodiments of the present disclosure, the abrasive grains contained in the polishing composition are preferably anion-modified silica, and more preferably anion-modified colloidal silica. The abrasive grains are more preferably colloidal silica having an organic acid immobilized on the surface thereof. Colloidal silica having an organic acid immobilized on the surface thereof tends to have a larger absolute value of zeta potential in the polishing composition compared to normal colloidal silica having no organic acid immobilized. Therefore, it is easy to adjust the zeta potential of colloidal silica in the polishing composition to −5 mV or less.

Preferable examples of the colloidal silica having an organic acid immobilized on the surface thereof include colloidal silica having an organic acid such as carboxylic acid, sulfonic acid, phosphonic acid, or aluminic acid immobilized on the surface thereof. Among these, from the viewpoint of easy production, colloidal silica having sulfonic acid or carboxylic acid immobilized on the surface thereof is preferable, and colloidal silica having sulfonic acid immobilized on the surface thereof is more preferable.

Immobilization of an organic acid on the surface of colloidal silica is not accomplished by simply allowing the colloidal silica and the organic acid to coexist. For example, immobilization of sulfonic acid, which is one type of organic acid, on colloidal silica can be carried out by, for example, the method described in “Sulfonic acid-functionalized silica through quantitative oxidation of thiol groups”, Chem. Commun. 246-247 (2003). Specifically, colloidal silica having sulfonic acid immobilized on the surface thereof (sulfonic acid-modified colloidal silica) can be obtained by coupling a silane coupling agent having a thiol group such as 3-mercaptopropyltrimethoxysilane to colloidal silica, followed by oxidation of the thiol group with hydrogen peroxide.

Alternatively, immobilization of carboxylic acid, which is one type of organic acid, on colloidal silica can be carried out by, for example, the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, colloidal silica having carboxylic acid immobilized on the surface thereof (carboxylic acid-modified colloidal silica) can be obtained by coupling a silane coupling agent containing a photoreactive 2-nitrobenzyl ester to colloidal silica, followed by photoirradiation.

There is no particular restriction on the shape of the abrasive grains, and it may be spherical or may be non-spherical. Specific examples of the non-spherical shape include, but are not particularly restricted to, various shapes such as a polygonal columnar shape such as a triangle pole and a square pole, a cylindrical shape, a straw bag shape in which the center part of the cylinder is swollen more than the end parts, a donut shape in which the center part of the disk is hollow, a plate shape, a so-called cocoon type shape having a constriction at the center part, a so-called associated type spherical shape in which a plurality of particles are integrated, a so-called kompeito shape having a plurality of protrusions on the surface, and a rugby ball shape.

There is no particular restriction on the size of the abrasive grains. For example, the average primary particle size of the abrasive grains is preferably 5 nm or more, more preferably 8 nm or more, still more preferably 10 nm or more, and particularly preferably 12 nm or more. As the average primary particle size of the abrasive grains increases, the polishing removal rate for the object to be polished by the polishing composition is improved. Also, the average primary particle size of the abrasive grains is preferably 100 nm or less, more preferably 80 nm or less, still more preferably 60 nm or less, and particularly preferably 50 nm or less. As the average primary particle size of the abrasive grains decreases, it becomes easier to obtain a surface with fewer defects by polishing using the polishing composition. That is, the average primary particle size of the abrasive grains is preferably 5 nm or more and 100 nm or less, more preferably 8 nm or more and 80 nm or less, still more preferably 10 nm or more and 60 nm or less, and particularly preferably 12 nm or more and 50 nm or less. Note that the average primary particle size of the abrasive grains can be calculated on the basis of the specific surface area (SA) of the abrasive grains, as calculated by the BET method, assuming that the shape of the abrasive grains is a true sphere, for example. In the present specification, as the average primary particle size of the abrasive grains, the value measured by the method described in Examples is employed.

Also, the average secondary particle size of the abrasive grains is preferably 10 nm or more, more preferably 15 nm or more, still more preferably 20 nm or more, and particularly preferably 25 nm or more. As the average secondary particle size of the abrasive grains increases, the resistance during polishing becomes smaller and polishing can be performed stably. Also, the average secondary particle size of the abrasive grains is preferably 400 nm or less, more preferably 300 nm or less, still more preferably 200 nm or less, and particularly preferably 100 nm or less. As the average secondary particle size of the abrasive grains decreases, the surface area per unit mass of the abrasive grains increases, which improves the frequency of contact with the object to be polished and further improves the polishing removal rate. That is, the average secondary particle size of the abrasive grains is preferably 10 nm or more and 400 nm or less, more preferably 15 nm or more and 300 nm or less, still more preferably 20 nm or more and 200 nm or less, and particularly preferably 25 nm or more and 100 nm or less. In the present specification, as the average secondary particle size of the abrasive grains, the value measured by the method described in Examples is employed.

The average degree of association of the abrasive grains is preferably 5.0 or less, more preferably 4.0 or less, still more preferably 3.0 or less, and particularly preferably 2.5 or less. As the average degree of association of the abrasive grains decreases, defects can be further reduced. Also, the average degree of association of the abrasive grains is preferably 1.0 or more, more preferably 1.5 or more, and still more preferably 2.0 or more. This average degree of association can be obtained by dividing the value of the average secondary particle size of the abrasive grains by the value of the average primary particle size. As the average degree of association of the abrasive grains increases, there is an advantageous effect that the polishing removal rate for the object to be polished by the polishing composition is improved.

Although there is no particular restriction on the upper limit of the aspect ratio of the abrasive grains in the polishing composition, it is preferably less than 2.0, more preferably 1.8 or less, and still more preferably 1.5 or less. Such a range can further reduce defects on the surface of the object to be polished. Note that the aspect ratio is the average of values obtained by defining the smallest circumscribed rectangles of images of abrasive grain particles by scanning electron microscopy and dividing the length of the longest side of those rectangles by the length of the short side of the same rectangles, and can be determined using common image analysis software. Although there is no particular restriction on the lower limit of the aspect ratio of the abrasive grains in the polishing composition, it is preferably 1.0 or more, and more preferably 1.2 or more.

Although there is no particular restriction on the lower limit of D90/D10, which is the ratio of the diameter of particles where the cumulative particle mass from the finer particle side reaches 90% of the entire particle mass (D90) to the diameter of particles where the cumulative particle mass reaches 10% of the entire particle mass (D10), in the particle size distribution of the abrasive grains determined by the laser diffraction scattering method, it is preferably 1.1 or more, more preferably 1.4 or more, still more preferably 1.7 or more, and most preferably 2.0 or more. In addition, although there is no particular restriction on the upper limit of D90/D10, which is the ratio of the diameter of particles where the cumulative particle mass from the finer particle side reaches 90% of the entire particle mass (D90) to the diameter of particles where the cumulative particle mass reaches 10% of the entire particle mass (D10), in the particle size distribution of the abrasive grains in the polishing composition determined by the laser diffraction scattering method, it is preferably 3.0 or less, and more preferably 2.5 or less. Such a range can further reduce defects on the surface of the object to be polished.

The sizes of the abrasive grains (such as average primary particle size, average secondary particle size, aspect ratio, and D90/D10) can be appropriately controlled by selection and the like of a method for producing the abrasive grains.

Although there is no particular restriction on the content (concentration) of the abrasive grains, it is preferably 0.5% by mass or more, more preferably 0.8% by mass or more, still more preferably 1% by mass or more, even more preferably more than 1% by mass, and particularly preferably 1.5% by mass or more with respect to the total mass of the polishing composition. Also, the upper limit of the content (concentration) of the abrasive grains is preferably 20% by mass or less, more preferably 15% by mass or less, still more preferably 10% by mass or less, and particularly preferably 5% by mass or less with respect to the total mass of the polishing composition. That is, the content (concentration) of the abrasive grains is preferably 0.5% by mass or more and 20% by mass or less, more preferably 0.8% by mass or more and 20% by mass or less, still more preferably 1% by mass or more and 15% by mass or less, even more preferably more than 1% by mass and 10% by mass or less, and particularly preferably 1.5% by mass or more and 5% by mass or less with respect to the total mass of the polishing composition. Such a range can improve the polishing removal rate while keeping costs down. Note that, in the case where the polishing composition contains two or more types of abrasive grains, the content (concentration) of the abrasive grains means their total amount.

### [Polyoxyalkylene Compounds]

The polishing composition according to the present disclosure contains a first polyoxyalkylene compound having a weight average molecular weight of 100 or more and 900 or less and a second polyoxyalkylene compound having an oxyalkylene unit different from that of the above first polyoxyalkylene compound and having a weight average molecular weight of 100 or more and 900 or less.

Here, as for “different oxyalkylene unit” possessed by the second polyoxyalkylene compound, the second polyoxyalkylene compound is defined as having an oxyalkylene unit different from that of the first polyoxyalkylene compound if it satisfies at least one of the following conditions, when compared to the oxyalkylene unit possessed by the first polyoxyalkylene compound:
(1) the number of carbon atoms in the alkylene moiety is different;
(2) the structure of the alkylene moiety is different (such as linear structure and branched structure);
(3) the number of types of oxyalkylene units is different (such as the case where the first polyoxyalkylene compound has only one type of oxyalkylene unit and the second polyoxyalkylene compound has two or more types of oxyalkylene units); and
(4) in the case where the first and second polyoxyalkylene compounds both have two or more types of oxyalkylene units, the arrangement of the oxyalkylene units is different (such as block, random, alternate, and periodic).

From the viewpoint that the first polyoxyalkylene compound and the second polyoxyalkylene compound can more easily have hydrophilicity that differs from each other, it is preferable that the above (1) is at least satisfied.

The first polyoxyalkylene compound and the second polyoxyalkylene compound have a weight average molecular weight (Mw) of 100 or more and 900 or less. Taking the case where the hydrophilicity of the first polyoxyalkylene compound is higher than the hydrophilicity of the second polyoxyalkylene compound as an example, in the case where the first polyoxyalkylene compound has a weight average molecular weight of less than 100, the residue cannot be sufficiently hydrophilized, and as a result, defects on the surface of the object to be polished that has been polished cannot be sufficiently reduced. On the other hand, in the case where the first polyoxyalkylene compound has a weight average molecular weight of more than 900, the polishing removal rate for a silicon-containing material (in particular, polysilicon) may decrease. Also, in the case where the second polyoxyalkylene compound has a weight average molecular weight of less than 100, it is difficult to be adsorbed by the residue, and even when combined with the first polyoxyalkylene compound, defects on the surface of the object to be polished that has been polished cannot be sufficiently reduced. On the other hand, in the case where the second polyoxyalkylene compound has a weight average molecular weight of more than 900, the polishing removal rate for a silicon-containing material (in particular, polysilicon) may decrease, and the second polyoxyalkylene compound itself becomes a residue, increasing defects on the surface of the object to be polished that has been polished.

It is preferable that the weight average molecular weight (Mw) of the first polyoxyalkylene compound and the second polyoxyalkylene compound is each independently 150 or more, and it may be 200 or more, 250 or more, 300 or more, 350 or more, or 400 or more. It is preferable that the weight average molecular weight (Mw) of the first polyoxyalkylene compound and the second polyoxyalkylene compound is each independently 850 or less, and it may be 800 or less, 750 or less, 700 or less, 650 or less, 600 or less, 550 or less, 500 or less, 450 or less, 400 or less, or less than 400.

Note that the weight average molecular weight (Mw) of the first polyoxyalkylene compound and the second polyoxyalkylene compound can be measured as the value in terms of polyethylene glycol using gel permeation chromatography (GPC), and specifically, it can be measured by the method described in Examples.

Although there is no particular restriction on the content (concentration) of the first polyoxyalkylene compound and the second polyoxyalkylene compound in the polishing composition according to the present disclosure, it is preferable that the content (concentration) is each independently 50 ppm by mass (0.005% by mass) or more with respect to the total mass of the polishing composition, and it may be 100 ppm by mass (0.01% by mass) or more, 150 ppm by mass (0.015% by mass) or more, 200 ppm by mass (0.02% by mass) or more, 250 ppm by mass (0.025% by mass) or more, 300 ppm by mass (0.03% by mass) or more, 400 ppm by mass (0.04% by mass) or more, 500 ppm by mass (0.05% by mass) or more, 600 ppm by mass (0.06% by mass) or more, 700 ppm by mass (0.07% by mass) or more, 800 ppm by mass (0.08% by mass) or more, 900 ppm by mass (0.09% by mass) or more, or 1000 ppm by mass (0.1% by mass) or more. In addition, although there is no particular restriction on the content (concentration) of the first polyoxyalkylene compound and the second polyoxyalkylene compound in the polishing composition according to the present disclosure, it is preferable that the content (concentration) is each independently 5000 ppm by mass (0.5% by mass) or less with respect to the total mass of the polishing composition, and it may be 4500 ppm by mass (0.45% by mass) or less, 4000 ppm by mass (0.4% by mass) or less, 3500 ppm by mass (0.35% by mass) or less, 3000 ppm by mass (0.3% by mass) or less, 2500 ppm by mass (0.25% by mass) or less, 2000 ppm by mass (0.2% by mass) or less, 1500 ppm by mass (0.15% by mass) or less, 1000 ppm by mass (0.1% by mass) or less, or less than 1000 ppm by mass (0.1% by mass).

In some embodiments, the content (concentration) of the first polyoxyalkylene compound in the polishing composition according to the present disclosure is preferably 200 ppm by mass (0.02% by mass) or more and 4000 ppm by mass (0.4% by mass) or less, more preferably 600 ppm by mass (0.06% by mass) or more and 3500 ppm by mass (0.35% by mass) or less, still more preferably 800 ppm by mass (0.08% by mass) or more and 3000 ppm by mass (0.3% by mass) or less, and particularly preferably 1000 ppm by mass (0.1% by mass) or more and 3000 ppm by mass (0.3% by mass) or less with respect to the total mass of the polishing composition. In addition, according to some embodiments, the content (concentration) of the second polyoxyalkylene compound is preferably 100 ppm by mass (0.01% by mass) or more and 2000 ppm by mass (0.2% by mass) or less, more preferably 150 ppm by mass (0.015% by mass) or more and 1500 ppm by mass (0.15% by mass) or less, still more preferably 200 ppm by mass (0.02% by mass) or more and 1000 ppm by mass (0.1% by mass) or less, and particularly preferably 200 ppm by mass (0.02% by mass) or more and less than 1000 ppm by mass (0.1% by mass) with respect to the total mass of the polishing composition.

In some embodiments, from the viewpoint of making it easier to have hydrophilicity that differs from each other, it is preferable that the weight average molecular weight of the first polyoxyalkylene compound is lower than the weight average molecular weight of the second polyoxyalkylene compound. In general, with such a weight average molecular weight relationship, the hydrophilicity of the first polyoxyalkylene compound is higher than the hydrophilicity of the second polyoxyalkylene compound, and the effect of the present disclosure is more easily expressed. Furthermore, in the present forms, it is preferable that the content of the first polyoxyalkylene compound in the polishing composition is higher than the content of the second polyoxyalkylene compound in the polishing composition. When the weight average molecular weight and content of the first polyoxyalkylene compound and the second polyoxyalkylene compound are in the relationships of large and small as described above, the hydrophilicity of the first polyoxyalkylene compound can be even higher than the hydrophilicity of the second polyoxyalkylene compound. This makes it easier for the residue on the surface of the object to be polished that has been polished to be further hydrophilized and for defects to be further reduced.

Some of more preferable forms of the relationships of large and small for the weight average molecular weight and content of the first polyoxyalkylene compound and the second polyoxyalkylene compound are as follows:
(i) weight average molecular weight
weight average molecular weight of the first polyoxyalkylene compound: 200 or more and less than 400
weight average molecular weight of the second polyoxyalkylene compound: 400 or more and 800 or less; and
(ii) content in the polishing composition
content of the first polyoxyalkylene compound: 1000 ppm by mass or more and 3000 ppm by mass or less
content of the second polyoxyalkylene compound: 200 ppm by mass or more and less than 1000 ppm by mass
content of the first polyoxyalkylene compound>content of the second polyoxyalkylene compound (the content of the first polyoxyalkylene compound is higher than the content of the second polyoxyalkylene compound).

As for the above (ii) content in the polishing composition, in the case where the content of the first polyoxyalkylene compound is higher than the content of the second polyoxyalkylene compound, the first polyoxyalkylene compound is more easily adsorbed by the residue, the residue can be sufficiently hydrophilized, and defects on the surface of the object to be polished that has been polished can be further reduced.

Specific examples of the first polyoxyalkylene compound include polyethylene glycol, polypropylene glycol, polytrimethylene glycol, polytetramethylene glycol, polypentamethylene glycol, polyhexamethylene glycol, polyethylene glycol-polypropylene glycol random copolymer, polyethylene glycol-polytetramethylene glycol random copolymer, polypropylene glycol-polytetramethylene glycol random copolymer, polyethylene glycol-polypropylene glycol-polytetramethylene glycol random copolymer, polyethylene glycol-polypropylene glycol block copolymer, polypropylene glycol-polyethylene glycol-polypropylene glycol triblock copolymer, and polyethylene glycol-polypropylene glycol-polyethylene glycol triblock copolymer.

Specific examples of the second polyoxyalkylene compound include the same compounds as for the first polyoxyalkylene compound above. However, in the present disclosure, the second polyoxyalkylene compound has an oxyalkylene unit different from that of the first polyoxyalkylene compound.

In one preferable embodiment, the above first polyoxyalkylene compound is polyethylene glycol and the above second polyoxyalkylene compound is polypropylene glycol.

### [pH and pH Adjusting Agent]

The polishing composition according to the present disclosure has a pH of less than 7. In the case where the polishing composition has a pH of 7 or more, the polishing removal rate for an object to be polished including a silicon-containing material (in particular, silicon nitride) is low. The pH is preferably 6.0 or less, more preferably 5.0 or less, and still more preferably 3.5 or less. Also, the pH is preferably 1.0 or more, more preferably 1.5 or more, and still more preferably 2.0 or more. That is, the pH of the polishing composition according to the present disclosure is preferably 1.0 or more and 6.0 or less, more preferably 1.5 or more and 5.0 or less, and still more preferably 2.0 or more and 3.5 or less.

The polishing composition according to the present disclosure may contain a pH adjusting agent for adjusting the pH. The pH adjusting agent may be either an acid or a base, and may be either an inorganic compound or an organic compound. As the pH adjusting agent, one type alone or a combination of two or more types can be used.

Specific examples of the acid that can be used as the pH adjusting agent include: inorganic acids such as hydrochloric acid, sulfuric acid, nitric acid, hydrofluoric acid, boric acid, carbonic acid, hypophosphorous acid, phosphorous acid, and phosphoric acid; and organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, and phenoxyacetic acid.

Examples of the base that can be used as the pH adjusting agent include amine compounds such as aliphatic amines and aromatic amines, hydroxides of alkali metals such as sodium hydroxide and potassium hydroxide, hydroxides of alkaline earth metals, and ammonia.

There is no particular restriction on the amount of the pH adjusting agent added, and it may be adjusted as appropriate so that the polishing composition has the desired pH. Also, the pH of the polishing composition can be measured with a pH meter, for example, and specifically, it can be measured by the method described in Examples.

Note that the inorganic salt and organic onium salt described below can also serve as the pH adjusting agent.

[Water-Soluble Polymer Other than Polyoxyalkylene Compounds]

It is preferable that the polishing composition according to the present disclosure further contains a water-soluble polymer other than the above polyoxyalkylene compounds (hereinafter, also simply referred to as “other water-soluble polymer”). The other water-soluble polymer is easily adsorbed by the surface of the object to be polished, and has the role of protecting the surface of the object to be polished. As a result, in the case where polishing is carried out using the polishing composition that contains the other water-soluble polymer, the number of defects on the surface of the object to be polished that has been polished can be further reduced.

The water-soluble polymer herein refers to a water-soluble polymer that has the same repeating unit (homopolymer) or a water-soluble polymer that has repeating units different from each other (copolymer), and typically, it can be a compound having a weight average molecular weight (Mw) of 100 or more. There is no particular restriction on the type of polymer used as the other water-soluble polymer, and any of anionic, cationic, nonionic, and amphoteric polymers can be used. Also, in the case where the other water-soluble polymer is a copolymer, the form of copolymer may be any of block copolymer, random copolymer, graft copolymer, alternating copolymer, and periodic copolymer.

Examples of the anionic water-soluble polymer include polyvinyl sulfonic acid, polystyrene sulfonic acid, polyallyl sulfonic acid, polymethallyl sulfonic acid, poly(2-acrylamido-2-methylpropane sulfonic acid), polyisoprene sulfonic acid, polyacrylic acid, and polymethacrylic acid.

Examples of the cationic water-soluble polymer include polyethyleneimine (PEI), polyvinylamine, polyallylamine, polyvinylpyridine, and cationic acrylamide polymer. As a specific example of polyallylamine, for example, polydiallyldimethylammonium chloride can be used.

Examples of the nonionic water-soluble polymer include water-soluble polymers other than polyoxyalkylene compounds, including polyvinyl alcohol, ethylene-vinyl alcohol copolymer, polyvinylpyrrolidone, polyacrylamide, poly-N-vinylacetamide, polyamine compounds, polyvinyl ether compounds (for example, polyvinyl methyl ether, polyvinyl ethyl ether, polyvinyl isobutyl ether, and the like), polyglycerin, polysaccharides such as water-soluble cellulose (for example, hydroxyethyl cellulose (HEC), hydroxypropyl cellulose, hydroxyethyl methyl cellulose, hydroxypropyl methyl cellulose, methyl cellulose, ethyl cellulose, ethyl hydroxyethyl cellulose, and the like), alginate polyhydric alcohol esters, water-soluble urea resins, dextrin derivatives, and casein. Also, not only those having such main chain structures, but also graft copolymers having a nonionic polymer structure in a side chain can be suitably used.

Examples of the amphoteric water-soluble polymer include copolymers of a vinyl monomer having an anionic group and a vinyl monomer having a cationic group, and vinyl-based amphoteric water-soluble polymers having a carboxybetaine group or a sulfobetaine group. Specific examples thereof include acrylic acid/dimethylaminoethyl methacrylate copolymer and acrylic acid/diethylaminoethyl methacrylate copolymer.

Furthermore, copolymers of the water-soluble polymers exemplified above can also be used.

These other water-soluble polymers can be used alone as one type, or may be used in combination of two or more types. In addition, commercial products of the water-soluble polymer may be used and synthetic products thereof may also be used.

Among these other water-soluble polymers, from the viewpoint of being able to further reduce defects on the surface of the object to be polished (in particular, silicon oxide) that has been polished, nonionic water-soluble polymers are preferable, and polyvinyl alcohol is more preferable.

The weight average molecular weight (Mw) of the other water-soluble polymer can be set as appropriate, depending on its type. In general, the lower limit of the weight average molecular weight (Mw) of the other water-soluble polymer is preferably 100 or more, and it may be 200 or more, 300 or more, 400 or more, 500 or more, 600 or more, 800 or more, 1,000 or more, 1,500 or more, 2,000 or more, 3,000 or more, 4,000 or more, or 5,000 or more. Also, the upper limit of the weight average molecular weight (Mw) of the other water-soluble polymer is preferably 500,000 or less, and it may be 100,000 or less, 50,000 or less, 30,000 or less, 20,000 or less, 10,000 or less, 8,000 or less, 5,000 or less, 3,000 or less, 2,000 or less, 1,000 or less, or 800 or less.

In one example, the weight average molecular weight (Mw) of the other water-soluble polymer may be 1,000 or more and 100,000 or less, 1,500 or more and 50,000 or less, 2,000 or more and 20,000 or less, 3,000 or more and 20,000 or less, or 5,000 or more and 20,000 or less. Also, in another example, the weight average molecular weight (Mw) of the other water-soluble polymer may be 100 or more and 2,000 or less, 200 or more and 2,000 or less, 200 or more and 1,000 or less, or 300 or more and 800 or less.

For example, in the case where the other water-soluble polymer is polyvinyl alcohol, the lower limit of the weight average molecular weight (Mw) of the polyvinyl alcohol may be 1,000 or more, 1,500 or more, 2,000 or more, 3,000 or more, or 5,000 or more. Also, the upper limit of the weight average molecular weight (Mw) of the polyvinyl alcohol may be 100,000 or less, 50,000 or less, or 20,000 or less. That is, the weight average molecular weight (Mw) of the polyvinyl alcohol may be 1,000 or more and 100,000 or less, 1,500 or more and 50,000 or less, 2,000 or more and 20,000 or less, 3,000 or more and 20,000 or less, or 5,000 or more and 20,000 or less.

The weight average molecular weight (Mw) of the other water-soluble polymer can be measured by the same method as for the weight average molecular weight (Mw) of the first polyoxyalkylene compound and the second polyoxyalkylene compound, and specifically, it can be measured by the method described in Examples.

The content (concentration) of the other water-soluble polymer in the polishing composition is preferably 100 ppm by mass (0.01% by mass) or more, more preferably 200 ppm by mass (0.02% by mass) or more, still more preferably 400 ppm by mass (0.04% by mass) or more, even more preferably 600 ppm by mass (0.06% by mass) or more, and particularly preferably 800 ppm by mass (0.08% by mass) or more with respect to the total mass of the polishing composition. Also, the upper limit of the content (concentration) of the other water-soluble polymer in the polishing composition is preferably 10,000 ppm by mass (1% by mass) or less, more preferably 8,000 ppm by mass (0.8% by mass) or less, still more preferably 6,000 ppm by mass (0.6% by mass) or less, even more preferably 5,000 ppm by mass (0.5% by mass) or less, and particularly preferably 4,000 ppm by mass (0.4% by mass) or less with respect to the total mass of the polishing composition.

That is, the content (concentration) of the other water-soluble polymer in the polishing composition is preferably 100 ppm by mass (0.01% by mass) or more and 10000 ppm by mass (1% by mass) or less, more preferably 200 ppm by mass (0.02% by mass) or more and 8000 ppm by mass (0.8% by mass) or less, still more preferably 400 ppm by mass (0.04% by mass) or more and 6000 ppm by mass (0.6% by mass) or less, even more preferably 600 ppm by mass (0.06% by mass) or more and 5000 ppm by mass (0.5% by mass) or less, and particularly preferably 800 ppm by mass (0.08% by mass) or more and 4000 ppm by mass (0.4% by mass) or less with respect to the total mass of the polishing composition.

Note that, in the case where the polishing composition contains two or more types of other water-soluble polymers, the content (concentration) of the other water-soluble polymer is intended to be their total amount.

### [Inorganic Salt]

It is preferable that the polishing composition according to the present disclosure further contains an inorganic salt. The inorganic salt has the function of further reducing defects on the surface of the object to be polished (in particular, silicon oxide) that has been polished. The inorganic salt also has the function of increasing the electrical conductivity of the polishing composition to further improve the polishing removal rate for the object to be polished.

Examples of the inorganic salt include inorganic salts composed of the cations and anions listed below. Examples of the cations include alkali metal ions such as lithium ion, sodium ion, and potassium ion, alkaline earth metal ions such as magnesium ion, calcium ion, and strontium ion, polyatomic ions such as ammonium ion, and complex ions. Examples of the anions include halide ions (such as fluoride ion, chloride ion, bromide ion, and iodide ion), oxoacid ions (borate ion, carbonate ion, nitrate ion, nitrite ion, metasilicate ion, phosphate ion, monohydrogen phosphate ion, dihydrogen phosphate ion, phosphonate ion, monohydrogen phosphonate ion, phosphinate ion, sulfate ion, sulfonate ion, sulfite ion, thiosulfate ion, chromate ion, dichromate ion, and permanganate ion), thiocyanate ion, cyanate ion, and sulfamate ion.

Further specific examples of the inorganic salt include: lithium salts such as lithium chloride, lithium bromide, lithium carbonate, lithium nitrate, and lithium thiocyanate; calcium salts such as calcium chloride, calcium bromide, calcium carbonate, calcium nitrate, and calcium thiocyanate; iron salts such as iron nitrate and iron thiocyanate; potassium salts such as potassium chloride, potassium bromide, potassium nitrate, potassium sulfate, potassium thiocyanate, potassium sulfamate, potassium phosphate, potassium dihydrogen phosphate, potassium monohydrogen phosphate, and potassium monohydrogen phosphonate; sodium salts such as sodium chloride, sodium bromide, sodium nitrate, sodium sulfate, and sodium thiocyanate; zinc salts such as zinc chloride, zinc nitrate, and zinc thiocyanate; magnesium salts such as magnesium nitrate, magnesium sulfate, and magnesium thiocyanate; strontium salts such as strontium nitrate and strontium thiocyanate; and ammonium salts such as ammonium chloride, ammonium bromide, ammonium iodide, ammonium nitrate, ammonium phosphate, ammonium dihydrogen phosphate, ammonium monohydrogen phosphate, ammonium phosphonate, ammonium monohydrogen phosphonate, ammonium sulfate, ammonium thiocyanate, and ammonium sulfamate. These inorganic salts can be used alone as one type, or may be used in combination of two or more types. In addition, commercial products of the inorganic salt may be used and synthetic products thereof may also be used.

Among these, from the viewpoint that the effect of the present disclosure is further demonstrated, it is preferable that the inorganic salt is at least one of an ammonium salt of an inorganic acid and a potassium salt of an inorganic acid. The inorganic acid is preferably sulfuric acid, nitric acid, or carbonic acid. Thus, the inorganic salt is more preferably at least one selected from the group consisting of ammonium sulfate, ammonium nitrate, ammonium carbonate, potassium sulfate, potassium nitrate, and potassium carbonate, and still more preferably ammonium sulfate.

Although there is no particular restriction on the content (concentration) of the inorganic salt in the polishing composition, it is preferably 100 ppm by mass (0.01% by mass) or more, more preferably 300 ppm by mass (0.03% by mass) or more, still more preferably 500 ppm by mass (0.05% by mass) or more, and particularly preferably 1000 ppm by mass (0.1% by mass) or more with respect to the total mass of the polishing composition. Also, the upper limit of the content (concentration) of the inorganic salt in the polishing composition is preferably 20000 ppm by mass (2.0% by mass) or less, more preferably 10000 ppm by mass (1.0% by mass) or less, still more preferably 8000 ppm by mass (0.8% by mass) or less, and particularly preferably 6000 ppm by mass (0.6% by mass) or less with respect to the total mass of the polishing composition.

That is, the content (concentration) of the inorganic salt is preferably 100 ppm by mass (0.01% by mass) or more and 20000 ppm by mass (2.0% by mass) or less, more preferably 300 ppm by mass (0.03% by mass) or more and 10000 ppm by mass (1.0% by mass) or less, still more preferably 500 ppm by mass (0.05% by mass) or more and 8000 ppm by mass (0.8% by mass) or less, and particularly preferably 1000 ppm by mass (0.1% by mass) or more and 6000 ppm by mass (0.6% by mass) or less with respect to the total mass of the polishing composition.

Note that, in the case where the polishing composition contains two or more types of inorganic salts, the content (concentration) of the inorganic salt means their total amount.

### [Organic Onium Salt]

It is preferable that the polishing composition according to the present disclosure further contains an organic onium salt. The organic onium salt has the function of further reducing defects on the surface of the object to be polished (in particular, silicon oxide) that has been polished.

The organic onium salt used in the present disclosure is preferably at least one of a tetraalkylammonium salt represented by the following chemical formula 1 and a tetraalkylphosphonium salt represented by the following chemical formula 2.

[Formula 1]

[NR¹R²R³R⁴]⁺A⁻ chemical formula 1

[PR⁵R⁶R⁷R⁸]⁺X⁻ chemical formula 2

In the above chemical formula 1 and chemical formula 2,
R¹ to R⁸ are each independently an unsubstituted alkyl group having 1 or more and 4 or less carbon atoms, and
A⁻ and X⁻ are each independently a monovalent anion.

If an organic onium salt is used that has an alkyl group having 5 or more carbon atoms, defects on the surface of the object to be polished that has been polished may increase.

Specific examples of the unsubstituted alkyl group having 1 or more and 4 or less carbon atoms used in R¹ to R⁸ in the above chemical formula 1 and chemical formula 2 include a methyl group, an ethyl group, a n-propyl group, an isopropyl group, a n-butyl group, a sec-butyl group, an isobutyl group, and a tert-butyl group. From the viewpoint that the effect of the present disclosure is further demonstrated, unsubstituted alkyl groups having 2 or more and 4 or less carbon atoms are preferable, such as an ethyl group, a n-propyl group, an isopropyl group, a n-butyl group, a sec-butyl group, an isobutyl group, and a tert-butyl group.

Suitable examples of the monovalent anion used in A⁻ and X⁻ in the above chemical formula 1 and chemical formula 2 include, but are not particularly restricted to, halide ions such as fluoride ion, chloride ion, bromide ion, and iodide ion; hydroxide ion; and organic acid ions such as benzoic acid ion. As the monovalent anion, one type alone or a combination of two or more types can be used. From the viewpoint that the effect of the present disclosure is further demonstrated, A⁻ and X⁻ in the above chemical formula 1 and chemical formula 2 are preferably hydroxide ions (OH⁻).

Further specific examples of the tetraalkylammonium salt represented by the above chemical formula 1 include: tetramethylammonium fluoride, trimethylethylammonium fluoride, dimethyldiethylammonium fluoride, methyltriethylammonium fluoride, tetraethylammonium fluoride, trimethyl-n-propylammonium fluoride, trimethylisopropylammonium fluoride, dimethylethyl-n-propylammonium fluoride, dimethylethylisopropylammonium fluoride, methyldiethyl-n-propylammonium fluoride, methyldiethylisopropylammonium fluoride, triethylisopropylammonium fluoride, triethyl-n-propylammonium fluoride, tetra-n-propylammonium fluoride, tetraisopropylammonium fluoride, tetra-n-butylammonium fluoride, and tetra-tert-butylammonium fluoride; tetramethylammonium chloride, trimethylethylammonium chloride, dimethyldiethylammonium chloride, methyltriethylammonium chloride, tetraethylammonium chloride, trimethyl-n-propylammonium chloride, trimethylisopropylammonium chloride, dimethylethyl-n-propylammonium chloride, dimethylethylisopropylammonium chloride, methyldiethyl-n-propylammonium chloride, methyldiethylisopropylammonium chloride, triethylisopropylammonium chloride, triethyl-n-propylammonium chloride, tetra-n-propylammonium chloride, tetraisopropylammonium chloride, tetra-n-butylammonium chloride, and tetra-tert-butylammonium chloride; tetramethylammonium bromide, trimethylethylammonium bromide, dimethyldiethylammonium bromide, methyltriethylammonium bromide, tetraethylammonium bromide, trimethyl-n-propylammonium bromide, trimethylisopropylammonium bromide, dimethylethyl-n-propylammonium bromide, dimethylethylisopropylammonium bromide, methyldiethyl-n-propylammonium bromide, methyldiethylisopropylammonium bromide, triethylisopropylammonium bromide, triethyl-n-propylammonium bromide, tetra-n-propylammonium bromide, tetraisopropylammonium bromide, tetra-n-butylammonium bromide, and tetra-tert-butylammonium bromide; tetramethylammonium iodide, trimethylethylammonium iodide, dimethyldiethylammonium iodide, methyltriethylammonium iodide, tetraethylammonium iodide, trimethyl-n-propylammonium iodide, trimethylisopropylammonium iodide, dimethylethyl-n-propylammonium iodide, dimethylethylisopropylammonium iodide, methyldiethyl-n-propylammonium iodide, methyldiethylisopropylammonium iodide, triethylisopropylammonium iodide, triethyl-n-propylammonium iodide, tetra-n-propylammonium iodide, tetraisopropylammonium iodide, tetra-n-butylammonium iodide, and tetra-tert-butylammonium iodide; tetramethylammonium hydroxide, trimethylethylammonium hydroxide, dimethyldiethylammonium hydroxide, methyltriethylammonium hydroxide, tetraethylammonium hydroxide, trimethyl-n-propylammonium hydroxide, trimethylisopropylammonium hydroxide, dimethylethyl-n-propylammonium hydroxide, dimethylethylisopropylammonium hydroxide, methyldiethyl-n-propylammonium hydroxide, methyldiethylisopropylammonium hydroxide, triethylisopropylammonium hydroxide, triethyl-n-propylammonium hydroxide, tetra-n-propylammonium hydroxide, tetraisopropylammonium hydroxide, tetra-n-butylammonium hydroxide, and tetra-tert-butylammonium hydroxide; and tetramethylammonium benzoate, trimethylethylammonium benzoate, dimethyldiethylammonium benzoate, methyltriethylammonium benzoate, tetraethylammonium benzoate, trimethyl-n-propylammonium benzoate, trimethylisopropylammonium benzoate, dimethylethyl-n-propylammonium benzoate, dimethylethylisopropylammonium benzoate, methyldiethyl-n-propylammonium benzoate, methyldiethylisopropylammonium benzoate, triethylisopropylammonium benzoate, triethyl-n-propylammonium benzoate, tetra-n-propylammonium benzoate, tetraisopropylammonium benzoate, tetra-n-butylammonium benzoate, and tetra-tert-butylammonium benzoate.

Further specific examples of the tetraalkylphosphonium salt represented by the above chemical formula 2 include: tetramethylphosphonium fluoride, trimethylethylphosphonium fluoride, dimethyldiethylphosphonium fluoride, methyltriethylphosphonium fluoride, tetraethylphosphonium fluoride, trimethyl-n-propylphosphonium fluoride, trimethylisopropylphosphonium fluoride, dimethylethyl-n-propylphosphonium fluoride, dimethylethylisopropylphosphonium fluoride, methyldiethyl-n-propylphosphonium fluoride, methyldiethylisopropylphosphonium fluoride, triethylisopropylphosphonium fluoride, triethyl-n-propylphosphonium fluoride, tetra-n-propylphosphonium fluoride, tetraisopropylphosphonium fluoride, tetra-n-butylphosphonium fluoride, and tetra-tert-butylphosphonium fluoride; tetramethylphosphonium chloride, trimethylethylphosphonium chloride, dimethyldiethylphosphonium chloride, methyltriethylphosphonium chloride, tetraethylphosphonium chloride, trimethyl-n-propylphosphonium chloride, trimethylisopropylphosphonium chloride, dimethylethyl-n-propylphosphonium chloride, dimethylethylisopropylphosphonium chloride, methyldiethyl-n-propylphosphonium chloride, methyldiethylisopropylphosphonium chloride, triethylisopropylphosphonium chloride, triethyl-n-propylphosphonium chloride, tetra-n-propylphosphonium chloride, tetraisopropylphosphonium chloride, tetra-n-butylphosphonium chloride, and tetra-tert-butylphosphonium chloride; tetramethylphosphonium bromide, trimethylethylphosphonium bromide, dimethyldiethylphosphonium bromide, methyltriethylphosphonium bromide, tetraethylphosphonium bromide, trimethyl-n-propylphosphonium bromide, trimethylisopropylphosphonium bromide, dimethylethyl-n-propylphosphonium bromide, dimethylethylisopropylphosphonium bromide, methyldiethyl-n-propylphosphonium bromide, methyldiethylisopropylphosphonium bromide, triethylisopropylphosphonium bromide, triethyl-n-propylphosphonium bromide, tetra-n-propylphosphonium bromide, tetraisopropylphosphonium bromide, tetra-n-butylphosphonium bromide, and tetra-tert-butylphosphonium bromide; tetramethylphosphonium iodide, trimethylethylphosphonium iodide, dimethyldiethylphosphonium iodide, methyltriethylphosphonium iodide, tetraethylphosphonium iodide, trimethyl-n-propylphosphonium iodide, trimethylisopropylphosphonium iodide, dimethylethyl-n-propylphosphonium iodide, dimethylethylisopropylphosphonium iodide, methyldiethyl-n-propylphosphonium iodide, methyldiethylisopropylphosphonium iodide, triethylisopropylphosphonium iodide, triethyl-n-propylphosphonium iodide, tetra-n-propylphosphonium iodide, tetraisopropylphosphonium iodide, tetra-n-butylphosphonium iodide, and tetra-tert-butylphosphonium iodide; tetramethylphosphonium hydroxide, trimethylethylphosphonium hydroxide, dimethyldiethylphosphonium hydroxide, methyltriethylphosphonium hydroxide, tetraethylphosphonium hydroxide, trimethyl-n-propylphosphonium hydroxide, trimethylisopropylphosphonium hydroxide, dimethylethyl-n-propylphosphonium hydroxide, dimethylethylisopropylphosphonium hydroxide, methyldiethyl-n-propylphosphonium hydroxide, methyldiethylisopropylphosphonium hydroxide, triethylisopropylphosphonium hydroxide, triethyl-n-propylphosphonium hydroxide, tetra-n-propylphosphonium hydroxide, tetraisopropylphosphonium hydroxide, tetra-n-butylphosphonium hydroxide, and tetra-tert-butylphosphonium hydroxide; and tetramethylphosphonium benzoate, trimethylethylphosphonium benzoate, dimethyldiethylphosphonium benzoate, methyltriethylphosphonium benzoate, tetraethylphosphonium benzoate, trimethyl-n-propylphosphonium benzoate, trimethylisopropylphosphonium benzoate, dimethylethyl-n-propylphosphonium benzoate, dimethylethylisopropylphosphonium benzoate, methyldiethyl-n-propylphosphonium benzoate, methyldiethylisopropylphosphonium benzoate, triethylisopropylphosphonium benzoate, triethyl-n-propylphosphonium benzoate, tetra-n-propylphosphonium benzoate, tetraisopropylphosphonium benzoate, tetra-n-butylphosphonium benzoate, and tetra-tert-butylammonium benzoate.

These organic onium salts can be used alone as one type, or can be used in combination of two or more types. In addition, commercial products of the organic onium salt may be used and synthetic products thereof may also be used.

Among these organic onium salts, from the viewpoint of more easily demonstrating the effect of the present disclosure, the organic onium salt is preferably a tetraalkylammonium salt represented by the above chemical formula 1, and more preferably at least one selected from the group consisting of tetraethylammonium hydroxide, tetrapropylammonium hydroxide, and tetra-n-butylammonium hydroxide.

The lower limit of the content (concentration) of the organic onium salt in the polishing composition is preferably 10 ppm by mass (0.001% by mass) or more, more preferably 15 ppm by mass (0.0015% by mass) or more, still more preferably 20 ppm by mass (0.002% by mass) or more, and particularly preferably 25 ppm by mass (0.0025% by mass) or more with respect to the total mass of the polishing composition. Also, the upper limit of the content (concentration) of the organic onium salt in the polishing composition is preferably 1000 ppm by mass (0.1% by mass) or less, more preferably 500 ppm by mass (0.05% by mass) or less, still more preferably 300 ppm by mass (0.03% by mass) or less, and particularly preferably 100 ppm by mass (0.01% by mass) or less with respect to the total mass of the polishing composition.

That is, the content (concentration) of the organic onium salt in the polishing composition is preferably 10 ppm by mass (0.001% by mass) or more and 1000 ppm by mass (0.1% by mass) or less, more preferably 15 ppm by mass (0.015% by mass) or more and 500 ppm by mass (0.05% by mass) or less, still more preferably 20 ppm by mass (0.002% by mass) or more and 300 ppm by mass (0.03% by mass) or less, and particularly preferably 25 ppm by mass (0.0025% by mass) or more and 100 ppm by mass (0.01% by mass) or less with respect to the total mass of the polishing composition.

Note that, in the case where the polishing composition contains two or more types of organic onium salts, the content (concentration) of the organic onium salt means their total amount.

### [Dispersing Medium]

It is preferable that the polishing composition according to the present disclosure further contains a dispersing medium. Examples of the dispersing medium can include: water; alcohols such as methanol, ethanol, and ethylene glycol; ketones such as acetone; and mixtures thereof. Of these, water is preferable as the dispersing medium. That is, according to more preferable forms of the present disclosure, the dispersing medium includes water. According to still more preferable forms of the present disclosure, the dispersing medium is substantially composed of water. Note that the term “substantially” described above is intended to mean that a dispersing medium other than water can be included as long as the object and effect of the present disclosure can be achieved, and more specifically, the dispersing medium is preferably composed of 90% by mass or more and 100% by mass or less of water and 0% by mass or more and 10% by mass or less of a dispersing medium other than water, and is more preferably composed of 99% by mass or more and 100% by mass or less of water and 0% by mass or more and 1% by mass or less of a dispersing medium other than water. Most preferably, the dispersing medium is water.

From the viewpoint of not inhibiting the action of the components contained in the polishing composition, water containing as few impurities as possible is preferable as the dispersing medium, and specifically, pure water or ultrapure water obtained by removing impurity ions with an ion exchange resin and then passing the water through a filter to remove foreign matter, or distilled water is more preferable.

### [Other Components]

The polishing composition of the present disclosure may further contain other components such as a complexing agent, a metal anticorrosive, an antiseptic agent, an antifungal agent, a reducing agent, and a surfactant, if necessary. Hereinafter, the preferable components, antiseptic agent and antifungal agent, will be described. Oxidizing agents will also be described.

### (Antiseptic Agent and Antifungal Agent)

Examples of the antiseptic agent and antifungal agent that can be added to the polishing composition according to the present disclosure include isothiazoline antiseptic agents such as 2-methyl-4-isothiazolin-3-one and 5-chloro-2-methyl-4-isothiazolin-3-one, paraoxybenzoic acid esters, and phenoxyethanol. These antiseptic agents and antifungal agents can be used alone as one type, or can be used in combination of two or more types.

### (Oxidizing Agents)

It is preferable that the polishing composition according to the present disclosure is substantially free from oxidizing agents. If an oxidizing agent is contained in the polishing composition, it may oxidize the surface of the object to be polished, producing an oxide film and prolonging the polishing time. Specific examples of the oxidizing agents here include hydrogen peroxide (H₂O₂), sodium persulfate, ammonium persulfate, and sodium dichloroisocyanurate. Note that the polishing composition being substantially free from oxidizing agents means that no oxidizing agents are intentionally contained, at the very least. Accordingly, polishing compositions that unavoidably contain a trace amount of oxidizing agents due to the raw materials, production method, and other factors are encompassed in the concept of the polishing composition that is substantially free from oxidizing agents here. For example, the content (concentration) of oxidizing agents in the polishing composition is preferably 100 ppm by mass (0.01% by mass) or less, more preferably less than 100 ppm by mass (0.01% by mass), and still more preferably 50 ppm by mass (0.005% by mass) or less. The lower limit of the content (concentration) of oxidizing agents is preferably 0 ppm by mass or more, and more preferably 5 ppm by mass (0.0005% by mass) or more.

### [Form of Polishing Composition]

The polishing composition according to the present disclosure is typically supplied to the object to be polished in the form of a polishing solution containing the polishing composition, and is used for polishing that object to be polished. The polishing composition according to the present disclosure may, for example, be diluted (typically diluted with water) and used as a polishing solution, or it may be used as is as a polishing solution. That is, the concept of the polishing composition according to the present disclosure encompasses both a polishing composition (working slurry) that is supplied to an object to be polished and used for polishing the object to be polished, and a concentrated solution (working slurry stock solution) that is diluted and then used for polishing. The concentration magnification of the above concentrated solution can be, for example, about 2 times or more and 100 times or less on a volume basis, and normally, about 3 times or more and 50 times or less is appropriate.

### [Object to be Polished]

The object to be polished according to the present disclosure is not particularly restricted, and examples thereof include silicon-containing materials such as monocrystalline silicon, polysilicon (polycrystalline silicon), polycrystalline silicon doped with n-type or p-type impurities, amorphous silicon, amorphous silicon doped with n-type or p-type impurities, silicon oxide, silicon nitride, and silicon carbonitride (SiCN); metals; and carbon-containing materials.

Examples of the object to be polished including silicon oxide include a TEOS-type silicon oxide film (hereinafter, also simply referred to as “TEOS” or “TEOS film”) that is formed using tetraethyl orthosilicate as a precursor, a HDP (High Density Plasma) film, an USG (Undoped Silicate Glass) film, a PSG (Phosphorus Silicate Glass) film, a BPSG (Boron-Phospho Silicate Glass) film, and a RTO (Rapid Thermal Oxidation) film.

Examples of the metals include tungsten, copper, aluminum, cobalt, hafnium, nickel, gold, silver, platinum, palladium, rhodium, ruthenium, iridium, and osmium.

Examples of the carbon-containing materials include amorphous carbon, spin-on carbon (SOC), diamond-like carbon (DLC), nanocrystalline diamond, and graphene.

As the object to be polished, commercial products may be used, or it may be produced by a known method.

Among these, the object to be polished including a silicon-containing material is preferable, and the object to be polished including silicon oxide is more preferable. Hence, according to one preferable embodiment of the present disclosure, the polishing composition is used for the application where the object to be polished including a silicon-containing material is polished.

### [Method for Producing Polishing Composition]

There is no particular restriction on the method for producing the polishing composition according to the present embodiment, and it can be obtained by, for example, stirring and mixing the abrasive grains, the first polyoxyalkylene compound, the second polyoxyalkylene compound, and other additives that are added if necessary. The details of each component are as described above.

There is no particular restriction on the temperature at which each component is mixed, but it is preferably 10° C. or higher and 40° C. or lower, and may be heated to increase the rate of dissolution. There is no particular restriction on the mixing time either, as long as uniform mixing can be achieved.

### [Polishing Method and Method for Producing Semiconductor Substrate]

As described above, the polishing composition according to the present embodiment is particularly suitably used for polishing an object to be polished including a silicon-containing material. Hence, the present disclosure provides a polishing method including: polishing an object to be polished including a silicon-containing material with the polishing composition according to the present embodiment. The present disclosure also provides a method for producing a semiconductor substrate, including: polishing a semiconductor substrate including a silicon-containing material by the above polishing method.

The polishing apparatus that can be used may be any general polishing apparatus to which a holder that holds a substrate or the like having an object to be polished, a motor whose rotation speed can be changed, and other components are attached, and that have a polishing table to which a polishing pad (polishing cloth) can be pasted.

As the polishing pad, general non-woven fabrics, polyurethanes, porous fluororesins, and others can be used with no particular restriction. It is preferable that the polishing pad has been grooved to allow the polishing solution to accumulate.

Regarding the polishing conditions, for example, the rotation speed of the polishing table (platen) and carrier (head) is preferably 10 rpm (0.17 s⁻¹) or more and 500 rpm (8.33 s⁻¹) or less. The pressure applied to the substrate having an object to be polished (polishing pressure) is preferably 0.5 psi (3.45 kPa) or more and 10 psi (68.9 kPa) or less.

There is no particular restriction on the method for supplying the polishing composition to the polishing pad either, and for example, a method is employed in which the polishing composition is continuously supplied with a pump or the like. There is no restriction on the amount supplied, but it is preferable that the surface of the polishing pad is always covered with the polishing composition according to the present disclosure.

The polishing composition according to the present embodiment may be of a single-fluid type or multi-fluid type including double-fluid type. Also, the polishing composition according to the present disclosure may be prepared by, for example, diluting a stock solution of the polishing composition by about 2 times or more and 100 times or less, normally 3 times or more and 50 times or less, on a volume basis, using a diluent such as water.

### [Polishing Removal Rate]

As described above, the polishing composition according to the present disclosure can realize a good polishing removal rate for a silicon-containing material.

In the present disclosure, the polishing removal rate for silicon nitride (or silicon nitride film) is preferably 600 Å/min or more, more preferably 650 Å/min or more, and still more preferably 680 Å/min or more. Also, the polishing removal rate for silicon oxide (or silicon oxide film) is preferably 300 Å/min or more, more preferably 340 Å/min or more, and still more preferably 350 Å/min or more. Furthermore, the polishing removal rate for polysilicon (or polysilicon film) is preferably 200 Å/min or more, more preferably 400 Å/min or more, and still more preferably 500 Å/min or more. Note that 1 Å=0.1 nm.

### [Number of Defects]

As described above, the polishing composition according to the present disclosure can reduce defects on the surface of the object to be polished that has been polished.

In the present disclosure, a smaller number of defects on the surface of the object to be polished that has been polished is preferable. As an example, the number of defects on the object to be polished having a silicon oxide film that has been polished is preferably 160 or less, more preferably 135 or less, still more preferably 130 or less, and particularly preferably less than 120 (lower limit: 0 defects). Note that the number of defects can be measured by the method described in Examples.

The embodiments of the present disclosure are described in detail above, but are given for explanatory and illustrative purposes only, and are not limited. The scope of the present disclosure should be obviously construed on the basis of the attached claims.

The present disclosure encompasses the following aspects and forms.
[1] A polishing composition containing: abrasive grains having a zeta potential of −5 mV or less; a first polyoxyalkylene compound having a weight average molecular weight of 100 or more and 900 or less; and a second polyoxyalkylene compound having an oxyalkylene unit different from that of the first polyoxyalkylene compound and having a weight average molecular weight of 100 or more and 900 or less, wherein the polishing composition has a pH of less than 7.
[2] The polishing composition according to the above [1], wherein the abrasive grains are anion-modified silica.
[3] The polishing composition according to the above [1] or [2], wherein the weight average molecular weight of the first polyoxyalkylene compound is lower than the weight average molecular weight of the second polyoxyalkylene compound.
[4] The polishing composition according to any of the above [1] to [3], wherein a content of the first polyoxyalkylene compound in the polishing composition is higher than a content of the second polyoxyalkylene compound in the polishing composition.
[5] The polishing composition according to any of the above [1] to [4], wherein the first polyoxyalkylene compound is polyethylene glycol and the second polyoxyalkylene compound is polypropylene glycol.
[6] The polishing composition according to any of the above [1] to [5], further containing an inorganic salt.
[7] The polishing composition according to any of the above [1] to [6], further containing an organic onium salt.
[8] The polishing composition according to any of the above [1] to [7], further containing a water-soluble polymer other than polyoxyalkylene compounds.
[9] The polishing composition according to any of the above [1] to [8], further containing a dispersing medium.
[10] The polishing composition according to any of the above [1] to [9], used for polishing an object to be polished including a silicon-containing material.
[11] The polishing composition according to the above [10], wherein the silicon-containing material is silicon oxide.
[12] A polishing method including: using the polishing composition according to any of the above [1] to [11] to polish an object to be polished including a silicon-containing material.
[13] A method for producing a semiconductor substrate, including: polishing a semiconductor substrate including a silicon-containing material by the polishing method according to the above [12].

### EXAMPLES

The present disclosure will be described in further detail using the following Examples and Comparative Examples. However, the technical scope of the present disclosure is not restricted to the following Examples alone. Note that, unless otherwise specified, “%” and “part(s)” refer to “% by mass” and “parts by mass”, respectively. Also, in the following Examples, unless otherwise specified, operations were carried out under conditions of room temperature (20° C. or higher and 25° C. or lower)/relative humidity of 40% RH or more and 50% RH or less. Note that each physical property was measured as follows.

### <Average Primary Particle Size and Average Secondary Particle Size of Abrasive Grains>

The average primary particle size of the abrasive grains was calculated from the specific surface area of the abrasive grains by the BET method measured using Flow Sorb II 2300 manufactured by Micromeritics Instrument Corporation and the density of the abrasive grains. Also, the average secondary particle size of the abrasive grains was measured as the volume average particle size (arithmetic mean size on a volume basis; Mv) using the dynamic light scattering particle size and particle size distribution apparatus UPA-UT151 (manufactured by Nikkiso Co., Ltd.).

### <Zeta Potential of Abrasive Grains>

The zeta potential of the abrasive grains in the polishing composition was calculated by subjecting the polishing composition to Zetasizer Nano manufactured by Malvern Panalytical, performing measurement by the laser Doppler method (electrophoretic light scattering measurement method) under conditions of a measurement temperature of 25° C., and analyzing the obtained data with the Smoluchowski equation for calculation.

### <pH of Polishing Composition>

The pH of the polishing composition was measured with a pH meter (manufactured by HORIBA, Ltd., model number: LAQUA).

### <Measurement of Molecular Weight of Polyoxyalkylene Compounds and Other Water-Soluble Polymer>

The weight average molecular weight of the polyoxyalkylene compounds and other water-soluble polymer were measured using gel permeation chromatography (GPC) under the following measurement conditions.

### (GPC Measurement Conditions)

Measurement apparatus: HLC-8320GPC (manufactured by TOSOH CORPORATION)
Sample concentration: 0.01% by mass
Column: TSKgel® GMPWXL
Detector: differential refractometer
Eluent: solution of 10 mM lithium bromide dissolved in N,N-dimethylformamide
Flow rate: 1 mL/min
Measurement temperature: 40° C.
Molecular weight conversion: in terms of polyethylene glycol
Sample injection volume: 200 μL

### [Production of Sulfonic Acid-Modified Colloidal Silica]

In accordance with the following procedures, sulfonic acid-modified colloidal silica as the abrasive grains was obtained.

### (Step of Preparing Raw Material Colloidal Silica Dispersion (Unmodified Silica Particles))

In a flask, 4080 g of methanol, 610 g of water, and 168 g of a 29 mass % aqueous ammonia solution were mixed, and while keeping the liquid temperature at 20° C., a mixed solution of 135 g of methanol and 508 g of tetramethoxysilane (TMOS) was added dropwise thereto over a dropping time of 25 minutes. Thereafter, heat concentration and water replacement were carried out under conditions of pH of 7 or more, and 1000 g of 19.5 mass % silica sol was obtained (average primary particle size: 34 nm, average secondary particle size: 70 nm).

### (Surface Modification Step)

Subsequently, to 1000 g of the silica sol obtained as described above (195 g in terms of silica solids), 1.2 g of 3-mercaptopropyltrimethoxysilane (MPS, silane coupling agent, product name: KBM-803, manufactured by Shin-Etsu Chemical Co., Ltd.), which had been separately mixed with 4.8 g of methanol, was added dropwise at a flow rate of 1 mL/min (content of silane coupling agent with respect to the total mass of silica solids: 0.6% by mass). The resultant mixture was then heated, and after boiling, pure water replacement was carried out for 3 hours.

Next, the above reaction solution was allowed to stand overnight to allow it to cool. 0.0343 g of 30 mass % hydrogen peroxide water (3 moles per mole of silane coupling agent) was added, and the mixture was brought to a boil again. Thereafter, pure water replacement was carried out for 2 hours, and then the resulting product was cooled to room temperature (25° C.) to obtain sulfonic acid-modified colloidal silica.

### Example 1

### <Preparation of Polishing Composition>

To water as the dispersing medium, the sulfonic acid-modified colloidal silica (average primary particle size: 34 nm, average secondary particle size, average secondary particle size: 70 nm), which was the abrasive grains produced in the above <Production of Sulfonic Acid-Modified Colloidal Silica>, was added so that the final content was 4% by mass, and a mixed solution was obtained. To this mixed solution, ammonium sulfate ((NH₄)₂SO₄) as the inorganic salt and tetraethylammonium hydroxide (TEAH) as the organic onium salt were added so that the respective final contents were 2000 ppm by mass (0.2% by mass) and 26 ppm by mass (0.0026 mass % by mass). Furthermore, polyethylene glycol (PEG) having a weight average molecular weight (Mw) of 200 as the first polyoxyalkylene compound, polypropylene glycol (PPG) having a weight average molecular weight (Mw) of 400 as the second polyoxyalkylene compound, and polyvinyl alcohol (PVA) having a weight average molecular weight (Mw) of 10000 as the water-soluble polymer other than polyoxyalkylene compounds were added so that the respective final contents were 200 ppm by mass (0.02% by mass), 600 ppm by mass (0.06% by mass), and 1000 ppm by mass (0.1% by mass), and the mixture was stirred and mixed (stirring temperature: 25° C., stirring time: 20 minutes). Thereafter, the pH of the polishing composition was adjusted to 2.1 using nitric acid to prepare a polishing composition 1.

### Example 2

A polishing composition 2 was prepared in the same manner as in Example 1, except that the amount of the polyethylene glycol having a weight average molecular weight (Mw) of 200 added was changed to such an amount that the final content was 600 ppm by mass (0.06% by mass).

### Example 3

A polishing composition 3 was prepared in the same manner as in Example 1, except that the amount of the polyethylene glycol having a weight average molecular weight (Mw) of 200 added was changed to such an amount that the final content was 1000 ppm by mass (0.1% by mass).

### Example 4

A polishing composition 4 was prepared in the same manner as in Example 1, except that the amount of the polyethylene glycol having a weight average molecular weight (Mw) of 200 added was changed to such an amount that the final content was 3000 ppm by mass (0.3% by mass).

### Example 5

A polishing composition 5 was prepared in the same manner as in Example 2, except that the first polyoxyalkylene compound was changed to polyethylene glycol having a weight average molecular weight (Mw) of 400.

### Example 6

A polishing composition 6 was prepared in the same manner as in Example 2, except that the first polyoxyalkylene compound was changed to polyethylene glycol having a weight average molecular weight (Mw) of 600.

### Example 7

A polishing composition 7 was prepared in the same manner as in Example 2, except that the first polyoxyalkylene compound was changed to polyethylene glycol having a weight average molecular weight (Mw) of 800.

### Example 8

A polishing composition 8 was prepared in the same manner as in Example 4, except that the amount of the polypropylene glycol having a weight average molecular weight (Mw) of 400 added was changed to such an amount that the final content was 200 ppm by mass (0.02% by mass).

### Example 9

A polishing composition 9 was prepared in the same manner as in Example 4, except that the amount of the polypropylene glycol having a weight average molecular weight (Mw) of 400 added was changed to such an amount that the final content was 1000 ppm by mass (0.1% by mass).

### Example 10

A polishing composition 10 was prepared in the same manner as in Example 4, except that the second polyoxyalkylene compound was changed to polypropylene glycol having a weight average molecular weight (Mw) of 200.

### Example 11

A polishing composition 11 was prepared in the same manner as in Example 4, except that the second polyoxyalkylene compound was changed to polypropylene glycol having a weight average molecular weight (Mw) of 800.

### Comparative Example 1

A polishing composition comparative 1 was prepared in the same manner as in Example 1, except that the first polyoxyalkylene compound and the second polyoxyalkylene compound were not used.

### Comparative Example 2

A polishing composition comparative 2 was prepared in the same manner as in Example 4, except that the second polyoxyalkylene compound was not used.

### Comparative Example 3

A polishing composition comparative 3 was prepared in the same manner as in Example 1, except that the first polyoxyalkylene compound was not used.

### Comparative Example 4

A polishing composition comparative 4 was prepared in the same manner as in Example 2, except that polyethylene glycol having a weight average molecular weight (Mw) of 600 was used in place of the polypropylene glycol having a weight average molecular weight (Mw) of 400.

### Comparative Example 5

A polishing composition comparative 5 was prepared in the same manner as in Example 2, except that polyethylene glycol having a weight average molecular weight (Mw) of 1540 was used in place of the polyethylene glycol having a weight average molecular weight (Mw) of 200.

The configurations of the polishing compositions of Examples 1 to 11 and Comparative Examples 1 to 5 are shown in Table 1 below. Note that the symbol “-” in Table 1 below indicates that the relevant component was not used.

TABLE 1

| | | Abrasive | | | | Organic | | Water-soluble | | |
|---|---|---|---|---|---|---|---|---|---|---|
| | | grains | | Inorganic salt | | onium salt | | polymer | | |
| | Polishing | Content | Zeta | | Content | | Content | | | Content |
| | composition | (% by | potential | | (ppm by | | (ppm by | | | (ppm by |
| | No. | mass) | (mV) | Type | mass) | Type | mass) | Type | Mw | mass) |
| Example | 1 | 4 | −25 | (NH₄)₂ | 2000 | TEAH | 26 | PVA | 10000 | 1000 |
| 1 | | | | SO₄ | | | | | | |
| Example | 2 | 4 | −25 | (NH₄)₂ | 2000 | TEAH | 26 | PVA | 10000 | 1000 |
| 2 | | | | SO₄ | | | | | | |
| Example | 3 | 4 | −25 | (NH₄)₂ | 2000 | TEAH | 26 | PVA | 10000 | 1000 |
| 3 | | | | SO₄ | | | | | | |
| Example | 4 | 4 | −25 | (NH₄)₂ | 2000 | TEAH | 26 | PVA | 10000 | 1000 |
| 4 | | | | SO₄ | | | | | | |
| Example | 5 | 4 | −25 | (NH₄)₂ | 2000 | TEAH | 26 | PVA | 10000 | 1000 |
| 5 | | | | SO₄ | | | | | | |
| Example | 6 | 4 | −25 | (NH₄)₂ | 2000 | TEAH | 26 | PVA | 10000 | 1000 |
| 6 | | | | SO₄ | | | | | | |
| Example | 7 | 4 | −25 | (NH₄)₂ | 2000 | TEAH | 26 | PVA | 10000 | 1000 |
| 7 | | | | SO₄ | | | | | | |
| Example | 8 | 4 | −25 | (NH₄)₂ | 2000 | TEAH | 26 | PVA | 10000 | 1000 |
| 8 | | | | SO₄ | | | | | | |
| Example | 9 | 4 | −25 | (NH₄)₂ | 2000 | TEAH | 26 | PVA | 10000 | 1000 |
| 9 | | | | SO₄ | | | | | | |
| Example | 10 | 4 | −25 | (NH₄)₂ | 2000 | TEAH | 26 | PVA | 10000 | 1000 |
| 10 | | | | SO₄ | | | | | | |
| Example | 11 | 4 | −25 | (NH₄)₂ | 2000 | TEAH | 26 | PVA | 10000 | 1000 |
| 11 | | | | SO₄ | | | | | | |
| Comparative | Comparative 1 | 4 | −25 | (NH₄)₂ | 2000 | TEAH | 26 | PVA | 10000 | 1000 |
| Example 1 | | | | SO₄ | | | | | | |
| Comparative | Comparative 2 | 4 | −25 | (NH₄)₂ | 2000 | TEAH | 26 | PVA | 10000 | 1000 |
| Example 2 | | | | SO₄ | | | | | | |
| Comparative | Comparative 3 | 4 | −25 | (NH₄)₂ | 2000 | TEAH | 26 | PVA | 10000 | 1000 |
| Example 3 | | | | SO₄ | | | | | | |
| Comparative | Comparative 4 | 4 | −25 | (NH₄)₂ | 2000 | TEAH | 26 | PVA | 10000 | 1000 |
| Example 4 | | | | SO₄ | | | | | | |
| Comparative | Comparative 5 | 4 | −25 | (NH₄)₂ | 2000 | TEAH | 26 | PVA | 10000 | 1000 |
| Example 5 | | | | SO₄ | | | | | | |

| | First | | | Second | | | | |
|---|---|---|---|---|---|---|---|---|
| | polyoxyalkylene | | | polyoxyalkylene | | | Polishing | |
| | compound | | | compound | | | composition | |
| | | | Content | | | Content | pH | |
| | | | (ppm by | | | (ppm by | adjusting | |
| | Type | Mw | mass) | Type | Mw | mass) | agent | pH |
| Example | PEG | 200 | 200 | PPG | 400 | 600 | Nitric | 2.1 |
| 1 | | | | | | | acid | |
| Example | PEG | 200 | 600 | PPG | 400 | 600 | Nitric | 2.1 |
| 2 | | | | | | | acid | |
| Example | PEG | 200 | 1000 | PPG | 400 | 600 | Nitric | 2.1 |
| 3 | | | | | | | acid | |
| Example | PEG | 200 | 3000 | PPG | 400 | 600 | Nitric | 2.1 |
| 4 | | | | | | | acid | |
| Example | PEG | 400 | 600 | PPG | 400 | 600 | Nitric | 2.1 |
| 5 | | | | | | | acid | |
| Example | PEG | 600 | 600 | PPG | 400 | 600 | Nitric | 2.1 |
| 6 | | | | | | | acid | |
| Example | PEG | 800 | 600 | PPG | 400 | 600 | Nitric | 2.1 |
| 7 | | | | | | | acid | |
| Example | PEG | 200 | 3000 | PPG | 400 | 200 | Nitric | 2.1 |
| 8 | | | | | | | acid | |
| Example | PEG | 200 | 3000 | PPG | 400 | 1000 | Nitric | 2.1 |
| 9 | | | | | | | acid | |
| Example | PEG | 200 | 3000 | PPG | 200 | 600 | Nitric | 2.1 |
| 10 | | | | | | | acid | |
| Example | PEG | 200 | 3000 | PPG | 800 | 600 | Nitric | 2.1 |
| 11 | | | | | | | acid | |
| Comparative | — | — | — | — | — | — | Nitric | 2.1 |
| Example 1 | | | | | | | acid | |
| Comparative | PEG | 200 | 3000 | — | — | — | Nitric | 2.1 |
| Example 2 | | | | | | | acid | |
| Comparative | — | — | — | PPG | 400 | 600 | Nitric | 2.1 |
| Example 3 | | | | | | | acid | |
| Comparative | PEG | 200 | 600 | PEG | 600 | 600 | Nitric | 2.1 |
| Example 4 | | | | | | | acid | |
| Comparative | PEG | 1540 | 600 | PPG | 400 | 600 | Nitric | 2.1 |
| Example 5 | | | | | | | acid | |

### [Evaluation]

### <Polishing Removal Rate>

Using the polishing compositions obtained in the above Examples and Comparative Examples, the surfaces of the objects to be polished were polished under the following polishing conditions. Note that, as the objects to be polished, a silicon wafer (300 mm, blanket wafer) having a polysilicon (Poly-Si) film with a thickness of 5000 Å formed on the surface thereof, a silicon wafer (300 mm, blanket wafer) having a P-TEOS film (TEOS film (silicon oxide film) formed by plasma CVD) with a thickness of 10000 Å formed on the surface thereof, and a silicon wafer (300 mm, blanket wafer) having a silicon nitride (SiN) film with a thickness of 3000 Å formed on the surface thereof were each used.

### (Polishing Conditions)

Polishing machine: FREX 300E manufactured by Ebara Corporation
Pad: rigid polyurethane pad IC1010 manufactured by NITTA DuPont Incorporated.
Polishing pressure: 2.0 psi (1 psi=6894.76 Pa, the same applies hereinafter)
Rotation speed of polishing table: 90 rpm
Rotation speed of carrier: 90 rpm
Supply of polishing composition: flowing
Amount of polishing composition supplied: 200 mL/min
Polishing time: 1 minute

The polishing removal rate was calculated by determining the thickness with an optical film thickness measuring instrument (RE-3500: manufactured by SCREEN Semiconductor Solutions Co., Ltd.) and dividing (thickness before polishing)−(thickness after polishing) by the polishing time.

### <Number of Defects>

For the silicon wafer having the P-TEOS film formed thereon, after the polishing treatment, the surface was brush cleaned using a 0.3 mass % aqueous NH₃ solution for 40 seconds, followed by rinsing with deionized water for 20 seconds to obtain the object to be polished that had been polished.

Thereafter, for the object to be polished that had been polished, the number of defects on the surface was evaluated using the optical inspection machine Surfscan® SP5, manufactured by KLA-Tencor Japan Ltd.

Specifically, the number of defects with a diameter of more than 60 nm was measured for the remaining portion of the object to be polished that had been polished, excluding the 5-mm wide portion from the outer edge of one face (the region from 0 mm to 5 mm when the outer edge is defined as 0 mm).

The evaluation results for polishing removal rate and number of defects are shown in Table 2 below. Note that, in Table 2 below, the silicon nitride film is denoted as “SiN”, the P-TEOS film is denoted as “SiO₂”, and the polysilicon film is denoted as “Poly-Si”.

TABLE 2

| | Polishing removal rate (Å/min) | | | Number of defects |
|---|---|---|---|---|
| | SiN | SiO₂ | Poly-Si | (counts) |
| Example 1 | 682 | 358 | 571 | 132 |
| Example 2 | 679 | 340 | 563 | 123 |
| Example 3 | 689 | 351 | 559 | 121 |
| Example 4 | 685 | 357 | 548 | 113 |
| Example 5 | 684 | 342 | 543 | 128 |
| Example 6 | 674 | 342 | 475 | 131 |
| Example 7 | 685 | 359 | 402 | 135 |
| Example 8 | 678 | 342 | 588 | 115 |
| Example 9 | 671 | 344 | 485 | 138 |
| Example 10 | 689 | 346 | 601 | 119 |
| Example 11 | 673 | 346 | 223 | 139 |
| Comparative Example 1 | 687 | 350 | 637 | 167 |
| Comparative Example 2 | 691 | 353 | 601 | 174 |
| Comparative Example 3 | 675 | 346 | 561 | 826 |
| Comparative Example 4 | 679 | 347 | 572 | 178 |
| Comparative Example 5 | 682 | 342 | 54 | 176 |

As is clear from Table 2 above, it was found that, in the case where the polishing compositions of Examples were used, defects on the surface of the object to be polished including silicon oxide that had been polished could be reduced. On the other hand, it was found that, in the case where the polishing compositions of Comparative Examples were used, defects on the surface of the object to be polished including silicon oxide that had been polished increased.

The present application is based on Japanese Patent Application No. 2024-154741 filed on Sep. 9, 2024, and the contents disclosed therein are incorporated herein by reference in their entirety.

1. A polishing composition comprising:
abrasive grains having a zeta potential of −5 mV or less;
a first polyoxyalkylene compound having a weight average molecular weight of 100 or more and 900 or less; and
a second polyoxyalkylene compound having an oxyalkylene unit different from that of the first polyoxyalkylene compound and having a weight average molecular weight of 100 or more and 900 or less,
wherein the polishing composition has a pH of less than 7.

2. The polishing composition according to claim 1, wherein the abrasive grains are anion-modified silica.

3. The polishing composition according to claim 1, wherein the weight average molecular weight of the first polyoxyalkylene compound is lower than the weight average molecular weight of the second polyoxyalkylene compound.

4. The polishing composition according to claim 3, wherein a content of the first polyoxyalkylene compound in the polishing composition is higher than a content of the second polyoxyalkylene compound in the polishing composition.

5. The polishing composition according to claim 3,
wherein the first polyoxyalkylene compound is polyethylene glycol, and
wherein the second polyoxyalkylene compound is polypropylene glycol.

6. The polishing composition according to claim 1, further comprising an inorganic salt.

7. The polishing composition according to claim 1, further comprising an organic onium salt.

8. The polishing composition according to claim 1, further comprising a water-soluble polymer other than polyoxyalkylene compounds.

9. The polishing composition according to claim 1, further comprising a dispersing medium.

10. The polishing composition according to claim 1, used for polishing an object to be polished including a silicon-containing material.

11. The polishing composition according to claim 10, wherein the silicon-containing material is silicon oxide.

12. A polishing method comprising: polishing an object to be polished including a silicon-containing material by using the polishing composition according to claim 1.

13. A method for producing a semiconductor substrate, comprising: polishing a semiconductor substrate including a silicon-containing material by the polishing method according to claim 12.
